(19) United States
(12) Patent Application Publication
(10) Pub. No.: US 2026/0353603 A1
(43) Pub. Date: Nov. 5, 2026

(54) MICRO-AXIAL PUMP WITH SEGMENTED OUTLET GUIDE VANE

(71) Applicant: HEWLETT PACKARD ENTERPRISE DEVELOPMENT LP, Spring, TX (US)

(72) Inventors: Laura Sofia Lester, Spring, TX (US); William Kirk Norton, III, Spring, TX (US)

(21) Appl. No.: 19/194,218

(22) Filed: Apr. 30, 2025

(51) Int. Cl. H05K 7/20; F04D 3/00; F04D 29/54; F04D 29/64

(52) U.S. Cl. CPC H05K 7/20272; F04D 29/548; F04D 29/648; F04D 3/00

(57) ABSTRACT

An axial pump for delivering liquid coolant to cool an electronic device includes an impeller and a rotor disposed in an impeller chamber and a stator that drives rotation of the rotor and impeller. The pump includes an optical guide vane (OGV) formed from a first OGV segment and a second OGV segment coupled together, each comprising vanes arranged to reduce swirling motion from the liquid. The first OGV segment has keying tabs protruding radially from its vanes. The second OGV segment is part of an OGV chamber disposed downstream of and coupled to the impeller chamber. The OGV chamber includes keying slots in which the keying tabs are received. The impeller chamber includes clamping supports extending axially into the keying slots. The keying tabs are axially clamped between the clamping supports and the keying slots, which may affix the first OGV segment relative to the second OGV segment.

### INTRODUCTION

Some information processing systems utilize liquid cooling techniques to remove heat from the system. In these systems, a liquid coolant is circulated in a loop through the information processing devices (e.g., servers, networking devices, etc.) of the system, and heat generating components thereof (e.g., processors) are thermally coupled (e.g., via cold plates) to the liquid coolant so that the liquid coolant absorbs heat from these components. As the now-heated coolant exits the information processing devices, it carries the heat to a cooling device (such as a heat exchanger) which cools the liquid back to a desired operating temperature, whereupon the cooled liquid is circulated through the loop once again, extracting more heat from the information processing devices.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operations. In the drawings:

FIG. 1 is a schematic block diagram illustrating an example pump.

FIG. 2 is a perspective view of another example pump.

FIG. 3 is an exploded view of the pump of FIG. 2.

FIG. 4 is an exploded perspective and partial section view of an impeller chamber subassembly of the pump of FIG. 2, including a perspective section of an impeller chamber thereof with the section taken along the vertical axial plane indicated by section lines 4-4 in FIG. 2.

FIG. 5 is a cross-section of the pump of FIG. 2, with the section taken along the vertical axial plane indicated by section lines 4-4 shown in FIG. 2.

FIG. 6 is another exploded perspective view of the impeller chamber subassembly of FIG. 5 with impeller/rotor subassembly thereof omitted.

FIG. 7 is another exploded perspective view of the impeller chamber subassembly of FIG. 5 with impeller/rotor subassembly thereof omitted.

FIG. 8 is a perspective view of a first outlet guide vane (OGV) segment of the pump of FIG. 2.

FIG. 9 is a side view of the first OGV segment of FIG. 8.

FIG. 10 is a front view of the first OGV segment of FIG. 8.

FIG. 11 is a top view of an OGV chamber and the first OGV segment of the pump of FIG. 2 in a coupled state.

FIG. 12 is a rear view of an impeller chamber of the pump of FIG. 2.

FIG. 13 is a perspective sectional view of the impeller chamber, the first OGV segment, and the OGV chamber in a coupled state, with the section taken along a diagonal axial plane indicated by the section lines 13-13 in FIG. 7.

FIG. 14A-14C are schematic sectional views showing clamping of keying tabs of the first OGV segment between keying slots of the OGV chamber and clamping supports of the impeller chamber of the pump of FIG. 2. The sections are taken along a radial surface indicated by section lines 14-14 in FIG. 12 within the region 14′ indicated in FIG. 11. FIG. 14A shows a first state in which the first OGV segment is clocked and flush contact with the keying tab. FIG. 14B shows a second state in which first OGV segment is not clocked and flush contact with the keying tab does not occur. FIG. 14C shows a third state in which first OGV segment is not clocked and flush contact with the keying tab does not occur

FIG. 15. is a schematic block diagram illustrating an example information processing device comprising the pump of FIG. 1.

FIG. 16 is schematic block diagram illustrating an example information processing system comprising the pump of FIG. 1.

### DETAILED DESCRIPTION

A liquid cooling loop uses one or more pumps to drive the circulation of the liquid through the loop. Often, these pumps are disposed in a so-called coolant distribution unit (CDU) which provides a centralized pumping unit which circulates the liquid collectively through multiple information processing devices (e.g., an entire rack, or multiple racks, of such devices). These pumps are usually very large, with the CDU often taking up a substantial portion of a rack, or in some cases a full rack.

In some cases, it may be desired to utilize relatively small pumps in liquid cooling loops, rather than the commonly used large CDU pumps. One advantage of using smaller pumps for liquid cooling information processing systems is that the smaller pumps can be more efficient than the larger pumps, in terms of the amount of liquid they can move per unit of energy spent. The smaller pumps can also fit in places that the large pumps will not, which opens opportunities for system designers to arrange their systems in new and potentially more efficient ways which would not have otherwise been possible. For example, smaller pumps can allow for a distributed pumping architecture to be utilized, in which each information processing device is provided with one or more small pumps localized to the device (e.g., disposed within, or adjacent to, the chassis of the device) to control the circulation of fluid locally through that device in an individualized manner, rather than using a single large centralized pumping unit to control the flow of fluid collectively through the devices. This distributed approach can improve efficiency and performance of the liquid cooling loop, potentially reducing power usage and noise while also delivering more coolant flow (and hence better cooling). In addition, this may also facilitate greater modularity and scalability of the system, as the pumping capacity of the system naturally scales along with the demand for cooling, since each new device added to the system brings its own pump(s) with it.

While having smaller pumps can in theory be advantageous, realizing these advantages can be challenging with existing pump technologies. Many existing pumps that can produce the needed levels of pressure and liquid flow rates for liquid cooling an information processing device are simply too large, or are too awkwardly shaped, to fit well within the densely packed environment of an information processing device. Other pumps (such as artificial heart pumps) may be small enough to fit in a space-constrained information processing device, but these generally have inadequate pumping characteristics (e.g., insufficient pressure, insufficient flow rates, poor efficiency, etc.) for the liquid cooling context. In other words, it is challenging to find pumps which both have a suitable small form factor and which have desired pumping characteristics.

Thus, to meet this unique combination of challenges, specialized pumps are being developed, such as the micro-axial pumps described in U.S. Pat. No. 11,015,608 B2, the contents of which are incorporated herein by reference in their entirety. An axial pump has an impeller (the part that moves within the liquid to drive the flow) that spins along an axis that is coaxial with a flow direction of the liquid, in contrast to centrifugal pumps which have impellers that spin along an axis transverse to the flow direction of the liquid. The axial arrangement, together with various other improvements, allows for the micro-axial pumps to have a form factor which is both extremely small and conveniently shaped (e.g., rectangular in cross-section), while still providing the same or better effectiveness and efficiency as larger pumps. For example, some micro-axial pumps under development may be similar in size and shape to a deck of cards while being capable of providing pressures and flow rates on the order of 4 GPM at 4 PSID (i.e., with a 4 PSI pressure drop), 2 GPM at 11.5 PSID, or 1 GPM at 13.9 PSID.

However, the axial nature of the pump can result in the flows of liquid, after having passed an impeller of the pump, spiraling circumferentially around the center axis of the output tube, meaning that the motion of the liquid may include both an axial component and a swirling (circumferential) component. Moreover, the motion may not be uniform, with some portions of the liquid flow swirling more than others. This swirling (circumferential) component of the motion of the liquid flow can reduce pump efficiency. To combat this, an output guide vane (OGV) may be added to the pump immediately downstream of the impeller, with the OGV reducing the swirling motion from the flows of liquid output from the impeller. In other words, the OGV may, in essence, collimate the output liquid flow, such that the movement of the output liquid flow is entirely axial, if possible, or at least has much less of a swirling component. However, the OGV can be challenging to manufacture, given the small size of the micro-axial pumps. The OGV comprises a central body with a circular cross-section that may taper (decrease in diameter) along an axial length of the body, and vanes that protrude radially outward from and spiral circumferentially and axially around the central body. The small form factor of the axial pumps may lead to the OGV being very small and its vanes having a steep wrap angle, both of which can make the OGV hard to manufacture.

It has been found that the OGV can be manufactured if it is broken into multiple parts along its axial length, which are manufactured separately and then joined together. This may be referred to herein as a segmented OGV. However, this raises technical challenges of its own. In particular, it has been attempted to couple a first segment of the OGV to a second segment of the OGV by using epoxy or other bonding agents (adhesives). The epoxy is deposited in a recess on an inner surface of the first segment, which can be very difficult given the very small size of the parts. To apply the epoxy in these challenging conditions in a repeatable manner at scale may require the use of automated high accuracy dispensing machinery. This equipment can be very costly and also complicated and time-consuming to operate, driving up the costs of the pumps and creating a bottleneck in the manufacturing process. And even with this expensive and complicated equipment, there is still some variability in epoxy dispensing amount and position, and thus issues with the bond can arise (discussed below). In addition, the small volume of epoxy or other bonding agent which is dispensed for each OGV coupling operation may lead to frequent clogging of nozzles, thus resulting in frequent purging of the dispensing nozzle, creating waste and increasing costs. Thus, assembly using epoxy (or other) bonding may be too difficult and costly to be practical, in some circumstances.

Furthermore, epoxy (or other bonding agents) have been found to fail on occasion when used in this application. This failure can be caused, in part, by the temperatures at which the pump operates. In addition, some liquid coolants commonly used in liquid cooling information processing systems, such as PGW (a mixture of water and propylene glycol), may have incompatibilities with the bonding agent and contribute to failure. Failure may also be caused (or contributed to) by variations in application of the bonding agent, such as not enough bonding agent being applied or applied in the wrong area. These failures can allow the OGV segments to become decoupled, which can impact the pump's performance and risk further failures of other parts inside the pump. In addition, the bonding agent failures can generate debris, which may flow downstream and possibly damage other components of a liquid cooling system in which the pump is deployed.

An additional challenge is that it can be difficult to accurately clock the first segment relative to the second segment. Clocking, in this context, means to achieve a predetermined rotational orientation of the segments relative to one another about their central axis, such that vanes on a circumference of one segment are properly aligned relative to corresponding vanes on a circumference of the other segment. If not properly clocked, there may be steps, ledges, or other discontinuities between misaligned vanes, which can disrupt the flow of liquid and create hydraulic losses that decrease pump efficiency. A person (or machine) assembling the first OGV segment onto the second OGV segment may find it difficult to know when they are properly clocked, and thus misalignments may occur. Even a slight misalignment can result in decreased pump efficiency.

Accordingly, to address the problems noted above (among other things), the present disclosure provides a segmented OGV for a micro-axial pump that has a first OGV segment and a second OGV segment that can be mechanically coupled together by interlocking keying tabs protruding axially from vanes of the first OGV segment with corresponding keying slots in an OGV chamber of which the second OGV segment is a part. This coupling may be purely mechanical, without reliance on epoxy or other bonding agents, thus avoiding the issues described above related to use of such bonding agents. In particular, the coupling between the first and second OGV segments is very secure and not subject to failure due to temperature, coolant compatibility, or bonding agent dispensing imprecision. Furthermore, the keying tabs and slots can be formed into the parts as they are manufactured without any noticeable increase in difficulty, cost, or time to manufacture. In addition, the keying tabs and keying slots not only couple the OGV segments together, they may also be configured to clock the first and second OGV segments relative to one another.

Multiple of the keying tabs may be distributed around the circumference of the first OGV segment. The keying tabs may extend circumferentially and axially along a sloped path—for example, along the same spiral path as the vanes from which they protrude. The keying slots may include an axially facing surface (axial slot surface) that follows a sloped (e.g., spiraling) path complementary to the corresponding keying tab such that, when the keying tab is inserted into the corresponding keying slot, the axial slot surface sits flush against an axially facing surface of the keying tab (first axial tab surface). In addition, an impeller chamber of the pump immediately upstream of the OGV may include clamping supports in corresponding locations to the keying tabs and keying slots. The impeller chamber is configured to be attached to an OGV chamber which includes the second OGV segment, and when so attached the clamping supports thereof extend into the keying slots behind the keying tabs such that the keying tabs are sandwiched between the clamping supports and the axial slot surfaces of the keying slots. In this state, the axial slot surface engages the first axial tab surface, and an axially facing surface of the support (axial support surface) engages a second axial tab surface opposite the first axial tab surface. The axial support surface follows a sloped (e.g., spiraling) path complementary to the corresponding keying tab such that, when engaged, the axial support surface sits flush against the second axial tab surface. Thus, when the impeller chamber is attached to the OGV chamber, the keying tab is axially clamped between and in flush contact with the keying slots on one side and the clamping supports on the other.

In some examples, the above-described engagement between the keying tabs, the keying slots, and the clamping supports fully constrains the position and orientation of the first OGV segment relative to segment OGV segment. In other words, when the keying tabs are clamped between the keying slots and the clamping supports, the first OGV segment cannot translate or rotate relative to the second OGV segment, effectively affixing the two parts rigidly together.

Moreover, in some examples, the keying slots and keying tabs are configured to assist in clocking the first and second OGV segments. In other words, in some examples, the engagement between the keying tabs, keying slots, and clamping supports not only mechanically couples the two segments together it also simultaneously clocks the two segments relative to one another around the rotation axis. The insertion of the keying tabs into the keying slots provides a gross level of clocking alignment, as side walls of the keying slots confine the keying tabs circumferentially within a limited range. In some cases, the gross clocking provided by insertion of the keying tabs into the keying slots may be sufficiently precise for a desired application. In other examples, more precise clocking may be desired, which can be achieved in various ways, including some described herein.

In some examples, more precise clocking may be provided by the clamping of the keying tabs between the axial surfaces of the keying slots and the clamping supports. In some examples, this more precise clocking can be achieved automatically as a byproduct of the clamping, without requiring any explicit manual clocking efforts. In some examples, due to the spiraling path of the keying tabs and the complementary sloped axial surfaces of the keying slots and clamping supports, flush contact between all of the engaging surfaces occurs in a limited range of orientations of the first OGV segment relative to the second OGV segment (assuming ideal surfaces, only one orientation will result in flush contact, but given inevitable manufacturing tolerances, there may be a small range of viable orientations). Therefore, if the first OGV segment is slightly rotationally misaligned relative to the second OGV segment (about the pump rotation axis) when clamping begins, as the keying tabs are clamped progressively tighter between the keying slots and clamping supports, the sloped surfaces will slide against one another and rotate the first OGV segment into the proper orientation. Thus, precise clocking can be achieved without the difficulty and risk of error associated with explicit manual clocking.

In other examples, manual clocking may be performed after insertion of the keying tabs into the keying slots. In some examples, the keying slots may serve as a visual and/or tactile guide to assist the assembler in the manual clocking. After the manual clocking, the clamping of the keying tabs between the keying slots and the clamping supports may fix the rotational orientation of the first OGV segment relative to the second OGV segment, thereby retaining the first and second OGV segments in the clocked orientation. In other words, in these examples, the clamping of the keying tabs locks in the clocked orientation.

Turning now to the figures, various devices, systems, and methods in accordance with nonlimiting aspects of the present disclosure will be described.

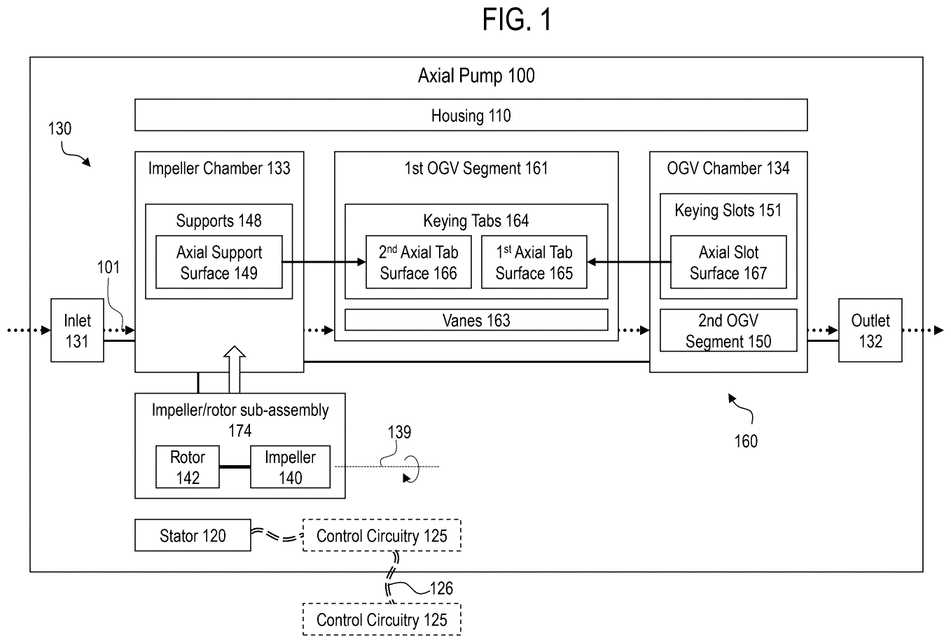

FIG. 1 is a schematic block diagram conceptually illustrating a pump 100. FIG. 1 is schematic in nature and is not intended to illustrate specific shapes, dimensions, positional relationships, or other structural details, except as otherwise noted herein. It should be understood that implementations of the pump 100 can vary from one another in various aspects. Some implementations of the pump 100 may have different numbers and arrangements of the illustrated components. Some implementations of the pump 100 may include other parts that are not illustrated in FIG. 1. Some implementations of the pump 100 may omit one or more of the parts that are illustrated in FIG. 1.

As shown in FIG. 1, the pump 100 comprises a housing 110 and a conduit 130 extending therethrough and defining a flow path for liquid coolant 101 (liquid 101) to traverse the pump 100. This conduit 130 includes an inlet 131, an impeller chamber 133, an outlet guide vane (OGV) chamber 134, and an outlet 132, which together define and enclose an internal volume forming the flow path for the liquid 101. The pump 100 also comprises an impeller/rotor subassembly 174 disposed in the impeller chamber 133 and rotatable relative thereto about a rotation axis 139 to drive the liquid 101 to flow through conduit 130. The pump 100 also comprises a pair of stators 120, which drive rotation of the impeller/rotor subassembly 174. The pump also comprises an OGV 160, which includes a first OGV segment 161 and a second OGV segment 150. The pump 100 may also include control circuitry 125. These components of the pump 100 will be described in greater detail below.

The housing 110 comprises one or more walls or other support structures that support and at least partially enclose or house some of the other components of the pump 100. The housing 110 may be a single part or made from multiple parts assembled together. In some examples, the parts of the housing 110 may also be coupled to and/or form an integral part of the other parts of the pump 100. For example, portions of the conduit 130 may also form parts of the housing 110.

The conduit 130 comprises walls that partially enclose a volume and define the flow path for liquid 101 through that volume. The liquid 101 may be water, water with additives (e.g., ethylene glycol, propylene glycol, etc.), or any other liquid coolant suitable for liquid cooling information processing components. In FIG. 1, the flow path of liquid 101 is suggested by dotted-line arrows. The conduit 130 comprises an inlet 131 having a first opening into the enclosed volume of the conduit 130, an impeller chamber 133, an OGV chamber 134, and an outlet 132 having a second opening into the enclosed volume of the conduit 130, with these portions of the conduit 130 being arranged axially adjacent one another. The impeller chamber 133 houses the impeller/rotor subassembly 174 and is fluidically coupled to the inlet 131 and the OGV chamber 134. The OGV chamber 134 comprises the second OGV segment 150, which is disposed in an internal bore of the OGV chamber 134, and the OGV chamber 134 is fluidically coupled with the impeller chamber 133 and outlet 132. The inlet 131 and outlet 132 may comprise structures for fluidically coupling the pump 100 with coolant lines of a liquid cooling loop, such as hose barbs, fittings, quick connect couplings, and/or other liquid coupling mechanisms as would be familiar to those of ordinary skill in the art. The conduit 130 may be liquid tight, with the interior volume being sealed from an exterior environment, other than at openings in the inlet 131 and outlet 132 that allow the enclosed interior volume to be fluidically coupled to the exterior environment (e.g., to coolant lines of a liquid cooling loop). In some examples, the inlet 131 and outlet 132 may extend outside of the housing 110 of the pump 100. In some examples, the impeller chamber 133 and OGV chamber 134 are contained within and/or form a portion of the housing 110.

The impeller/rotor subassembly 174 comprises an impeller 140 and a rotor 142 attached together and disposed within the conduit 130. The impeller/rotor subassembly 174 may also comprise a shaft (not illustrated). In some examples, the shaft is fixedly attached to the conduit 130 and the rotor 142 and/or impeller 140 are rotatably coupled to the shaft. In other examples, rotor 142 and/or impeller 140 may be fixedly coupled to the shaft and the shaft may be rotatable coupled to the conduit 130. In either case, the rotor 142 and impeller 140 rotate relative to the conduit 130. The impeller 140 and the rotor 142 will be described in greater detail in turn below.

A rotation axis of the rotor 142, a rotation axis of the impeller 140, a longitudinal axis of the shaft (if present), a central axis of the conduit 130, and central axes of the parts the from the conduit 130, are all coaxial with each other. These coaxial axes may all be referred to herein using the same reference number “139” and may be referred to interchangeably as the axis 139 or rotation axis 139. References such as “axial,” “radial,” “circumferential” and the like should be understood in relation to this axis 139, unless indicated otherwise. Liquid flowing through the conduit 130 flows along directions parallel to the axis 139, as indicated by the dashed arrows representing the flow path of liquid 101 in FIG. 1. Note that the liquid may also spiral circumferentially around the axis 139 (in addition to moving axially) while traversing certain portions of the flow path (e.g., while passing the impeller 140), but the bulk or average motion of the liquid as a whole in traversing the conduit 130 is axial, i.e., parallel to the axis 139. This is in contrast, for example, to circumferential pumps where the liquid flow path changes direction in the pump, for example beginning in an axial direction and then bending to extend radially, such that the average flow direction while traversing the pump is not axial. The flow path of the liquid 101 is shown in FIG. 1 to illustrate operation of the pump 100, but note that the liquid is not necessarily part of the pump 100 and is not necessarily present when the pump 100 is not deployed for operation.

The impeller 140 is housed within the conduit 130, specifically in the impeller chamber 133 thereof. The impeller 140 is configured to, when rotated about the axis 139, drive liquid to flow axially through the conduit 130. The impeller 140 comprises an impeller body and blades (not illustrated) that protrude radially from and spiral along/around the impeller body. References to the blades spiraling along or around the impeller body mean that the blades extend along paths that axially traverse the impeller body while simultaneously circling circumferentially around the impeller body through at least portions of the path; for example, the paths could be helical. The blades are configured to force the liquid axially through the conduit 130 as the impeller 140 rotates. In some examples, the impeller body and the impeller blades are integrally connected, meaning they are formed together as two parts of the same monolithic body. The impeller body may be formed from any solid material which can be formed into the desired shape. For example, the impeller body may be formed from various plastics, which can be formed into the desired shape by injection molding, additive manufacturing (e.g., 3D printing), or other techniques. As another example, the impeller body may be formed from various metals, which can be formed into the desired shape by casting, additive manufacturing (e.g., 3D printing), or other techniques.

The rotor 142 is fixedly coupled to the impeller 140. For instance, in some examples, the impeller body may be hollow (i.e., has an internal bore therethrough) and the rotor 142 may be at least partially contained within the hollow interior of the impeller 140. The rotor 142 comprises magnetic portions configured to interact with magnetic fields generated by the stator 120 to cause the rotor 142, and hence the impeller 140 attached thereto, to rotate. Thus, the rotor 142 and the stator 120 may together form an electromagnetic motor. The magnetic portions may comprise permanent magnets and/or magnetically attractable (e.g., ferromagnetic) materials (e.g., iron, steel, etc.) which are capable of interacting with (e.g., being attracted or repelled by) the generated magnetic fields. In some examples, the magnetic portions comprise multiple permanent magnets which are distributed circumferentially around the axis 139 and arranged with alternating polarities. In some examples, rotor 142 also comprises various bearings (e.g., ball bearings, plain bearings, etc.) to rotatably couple the rotor 142 to the shaft. The rotor 142 may include support structures (not illustrated) to support and couple the various parts of the rotor 142 together.

The stator 120 is configured to receive electrical driving signals and in response generate alternating magnetic fields that interact with the rotor 142 of the impeller/rotor subassembly 174 to cause the rotor 142 to rotate about axis 139. The stator 120 may comprise wire windings or other electrically conductive materials to generate the magnetic fields and/or magnetically susceptible materials to transfer and distribute the generated fields around the impeller/rotor subassembly 174 in a desired pattern. In some examples, the stator 120 comprises two portions arranged on opposite lateral sides of the conduit 130. The rotor 142 is contained in the conduit 130 between the two portions of the stator 120. U.S. Pat. No. 11,015,608 B2 describes example stators that are split into two portions, and these, for example, may be used as the stator 120.

The stator 120 may receive the electrical driving signals from control circuitry 125. This control circuitry 125 may be part of the pump 100 in some examples, or part of some other device or system external to the pump 100 in other examples. In some examples, stator 120 may be directly electrically connected to the control circuitry 125, for instance by wire windings of the stator 120 being soldered directly to a printed circuit assembly (PCA) of the control circuitry 125. In other examples, the stator 120 may be connected to the control circuitry 125 indirectly via cables or other intermediaries. The control circuitry 125 is configured to control operations of the pump 100. In some examples the control circuitry 125 comprises a PCA with various electronic components formed therein and/or mounted thereon, and/or additional components external to the PCA. In some examples the control circuitry 125 includes logic to drive operations of the pump 100. For example, control circuitry 125 may include a microcontroller. As another example, the control circuitry 125 may include discrete logic circuits (digital or analog), in addition to or instead of a microcontroller. The control circuitry 125 may also include sensors, such as temperature sensors, electrical power usage sensors, moisture sensors (e.g., for leak detection), magnetic field (e.g., Hall effect) sensors, or other sensors. The control circuitry 125 may also include power delivery components, such as transistors or other switches (e.g., relays), capacitors, diodes, etc. In some examples, the control circuitry 125 may include communications components for communicating with outside devices such as a system controller, baseboard management controller (BMC), rack controller, etc., for example via the cables (not illustrated) coupled to the pump 100 and/or wirelessly (via, e.g., Bluetooth, WiFi, etc.). The control circuitry 125 may be electrically coupled to the motor stator 120 to provide electrical signals thereto to drive the operation of the stator 120.

The pump 100 may also include a cable 126, which can electrically connect the pump 100 to external devices, from which the pump 100 may receive electrical signals that supply power and/or exchange communications. In some examples in which the control circuitry 125 is part of the pump 100, the cable 126 may extend from control circuitry 125 to an external device (or a connector which may be connected to the external device). In some examples in which the control circuitry 125 is external to the pump, the cable 126 may extend from the stator 120 to the control circuitry 125 (or a connector which may be connected, directly or indirectly, to the control circuit 125).

The OGV 160 is configured to reduce swirling motion from the flows of liquid 101 downstream of the impeller 140. The OGV 160 is a segmented OGV formed from multiple segments, including the first OGV segment 161 and the second OGV segment 150. In some examples, the OGV 160 may include additional segments (not illustrated). The segments of the OGV 160 are arranged in series along axis 139, with each segment being coupled to the adjacent segment(s). The first OGV segment 161 comprises a central body (“first central body”) and vanes 163 (“first vanes”) protruding radially from the central body and spiraling circumferentially thereabout and axial therealong. Although not illustrated, the second OGV segment 150 also includes a central body (“second central body”) and vanes (“second vanes”) protruding radially therefrom and spiraling circumferentially thereabout and axial therealong. If other OGV segments are present, they may also include a central body and vanes. The vanes of the various OGV segments may guide the liquid flowing through conduit 130 along liquid flow paths configured to help remove some or all of the swirling (circumferential) motion from the liquid 101. The central bodies and vanes of the various OGV segments are not necessarily all the same as one another. For example, some of the central bodies may be ring (hollow cylinder) shaped while others may taper along an axial direction. Furthermore, a wrap angle of the vanes may change from one segment to another and/or along an axial length of a given segment.

The second OGV segment 150 is part of the OGV chamber 134. The OGV chamber 134 includes conduit walls that are part of the conduit 130 and define a central volume or bore which forms part of the liquid flow path of conduit 130. The second OGV segment 150 is contained within this central volume or bore of the OGV chamber 134, with the second OGV segment 150 be affixed to the conduit walls of the OGV chamber 134. Thus, the second OGV segment 150 is a part of the OGV chamber. In some examples, the second OGV segment 150 is coupled to the conduit walls by the vanes of the second OGV segment 150, which may have one end joined to the central body of the second OGV segment 150 and an opposite end joined to, e.g., integrally formed with, the conduit walls.

The impeller chamber 133 may include a first engagement portion and the OGV chamber 134 may include a second engagement portion, with these two engagement portions mating to couple these chambers 133 and 134 together. The first OGV segment 161 may be disposed at a coupling between these engagement portions of the impeller chamber 133 and the OGV chamber 134, such that the first OGV segment 161 may be housed in impeller chamber 133, in the OGV chamber 134, or partially in both chambers 133 and 134.

The first OGV segment 161 and the second OGV segment 150 are mechanically coupled together. More specifically, the first OGV segment 161 includes keying tabs 164 protruding axially outward from the vanes 163. Multiple of the keying tabs 164 may be distributed around the circumference of the first OGV segment 161. For example, in some implementations, each vane 163 may have a keying tab 164 protruding therefrom. In addition, OGV chamber 134 comprises keying slots 151 corresponding to the keying tabs 164. The keying tabs 164 are configured to be inserted into the keying slots 151 when the pump 100 is assembled. In addition, the impeller chamber 133 includes clamping supports 148 in corresponding locations to the keying tabs 164 and keying slots 151. Thus, when the impeller chamber 133 is mated with the OGV chamber 134, the clamping supports 148 extend axially into the keying slots 151 and contact the keying tabs 164 such that the keying tabs 164 are axially clamped between the clamping supports 148 and the keying slots 151. This clamping of the keying tabs 164 between the clamping supports 148 and keying slots 151 mechanically affixes the first OGV segment 161 relative to the second OGV segment 150. In this context, “affixes” means that relative translation and relative rotation between first and second OGV segments 161 and 150 is prevented, including rotation about axis 139 (e.g., roll), rotation about axes perpendicular to axis 139 (e.g., pitch and yaw), and translation in any direction.

In some examples, the positions of the keying slots 151 and clamping supports 148 could be reversed, such that the keying slots 151 are part of the impeller chamber 133 and the clamping supports 148 are part of the OGV chamber 134. For example, the keying slots 151 may be recessed axially forward from a rear edge of an engagement portion of the impeller chamber 133, while the clamping supports 148 may protrude axially forward from an engagement portion of the OGV chamber 134.

References herein to a component A being “clamped between” two other components B and C, or equivalently references to the components B and C “clamping” component A therebetween, mean that the clamping components B and C are disposed on opposite sides of the clamped component A and are both in contact with opposite surfaces of A. References to “axially clamping,” or the like mean that the clamping components are disposed on opposite axial sides of the clamped component, such that the surfaces which contact one another in the clamping are generally axially facing—in other words, a clamping axis, which is a line which extends between the clamping components and through the clamped component, is generally axial (i.e., within 45° of axial).

The keying tabs 164 may extend circumferentially and axially along a path—for example, along the same spiral path as the vanes 163 from which they protrude. Each keying tab 164 has a first axial tab surface 165, which is a surface of the keying tab 164 which faces, at a geometric center thereof, generally in a first axial direction. Each keying tab 164 also has a second axial tab surface 166, which is a surface thereof opposite from the first axial tab surface, i.e., a surface which faces, at a geometric center thereof, generally in a second axial direction opposite the first axial direction. Reference to facing “generally” in an axial direction means facing in a direction that is within 45° of being parallel to the rotation axis 139. The direction a surface “faces” may be determined at a specified point on the surface and may be a direction that is normal (perpendicular) to the surface at that point (if no point is specified or implied, then it may be understood to be the geometric center of the surface).

The keying slots 151 may include an axial slot surface 167, which is a surface of the keying slot 151 that faces generally in the second axial direction. When the keying tabs 164 are inserted into the keying slots 151, the axial slot surfaces 167 of the keying slots 151 may contact the first axial tab surfaces 165 of the corresponding keying tabs 164. In some examples, the axial slot surface 167 may be sloped and/or curved so as to be complementary to the first axial tab surface 165 of the corresponding keying tab 164, and thus, when engaged, the axial slot surface 167 may make flush contact with the first axial tab surface 165.

Further, each of the clamping supports 148 may include an axial support surface 149, which is a surface of the support 148 that faces generally in the first axial direction. Thus, when clamping supports 148 are inserted into the keying slots 151 (e.g., when the impeller chamber 133 is coupled to the OGV chamber 134), the axial support surfaces 149 of the clamping supports 148 contact the second axial tab surfaces 166 of the corresponding keying tabs 164. In some examples, the axial support surface 149 may be sloped and/or curved so as to be complementary to the second axial tab surface 166 of the corresponding keying tab 164, and thus, when engaged, the axial support surface 149 may make flush contact with the second axial tab surface 166.

Thus, when the keying tabs 164 are inserted into the keying slots 151 and the impeller chamber 133 is attached to the OGV chamber 134, the keying tabs 164 may be clamped between, and in flush contact, with the axial slot surfaces 167 of keying slots 151 on one side and the axial support surfaces 149 of clamping supports 148 on the other.

References herein to “flush” contact between the various axial surfaces mean that there is substantial continuous contact between the surfaces along the region of axial overlap therebetween, excluding negligible gaps such as those occurring due to surface roughness or at the molecular scale. In this context, the axial surfaces for which flush contact is being judged may exclude holes, cutouts, chamfers, or other such surface features formed in the parts which deviate from the predominant curve or slope of the surface, etc. “Substantial” in this context means that the continuous contact occurs across a majority of the region of axial overlap between the surfaces. Thus, “flush” as used herein allows for small deviations from perfection, such as may arise due to manufacturing tolerances.

The above-described clamping of the keying tabs 164 between the keying slots 151 and the clamping supports 148 may fully constrain the position and orientation of the first OGV segment 161 relative to second OGV segment 150, thus effectively affixing the two parts rigidly together (both in translation and rotation). If the first OGV segment 161 was clocked relative to the second OGV segment 150 before the clamping, then the clamping may lock in the clocking, i.e., prevent subsequent relative rotation between the first OGV segment 161 and second OGV segment 150. In some examples, the clamping may itself result in clocking the first OGV segment 161 relative to second OGV segment 150.

In some examples, the keying slots 151 may be included in the portion of the conduit walls of the OGV chamber 134 that form the engagement portion of the OGV chamber 134. For example, the keying slots 151 may be recessed axially from a leading edge of the conduit walls of the engagement portion of the OGV chamber 134. Further, the clamping supports 148 may be formed in the engagement portion of the impeller chamber 133. For example, the clamping supports 148 protruding radially inward from an inner surface of the engagement portion of the impeller chamber 133. In some examples, the engagement portion of the OGV chamber 134 is received within the engagement portion of the impeller chamber 133, thereby mating the chambers 133 and 134 together.

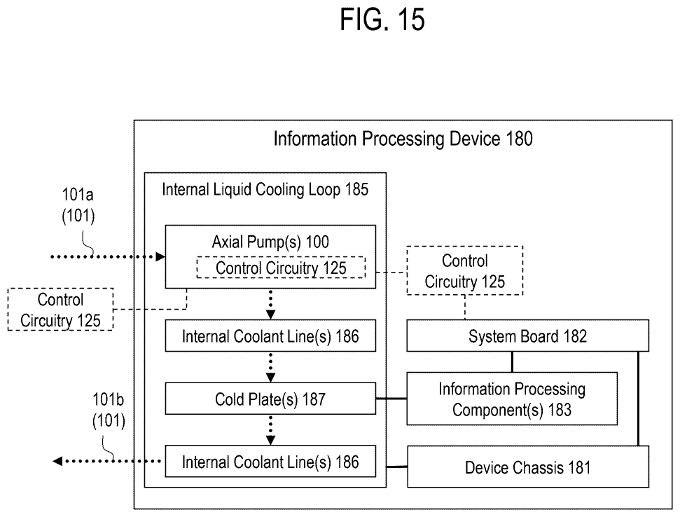

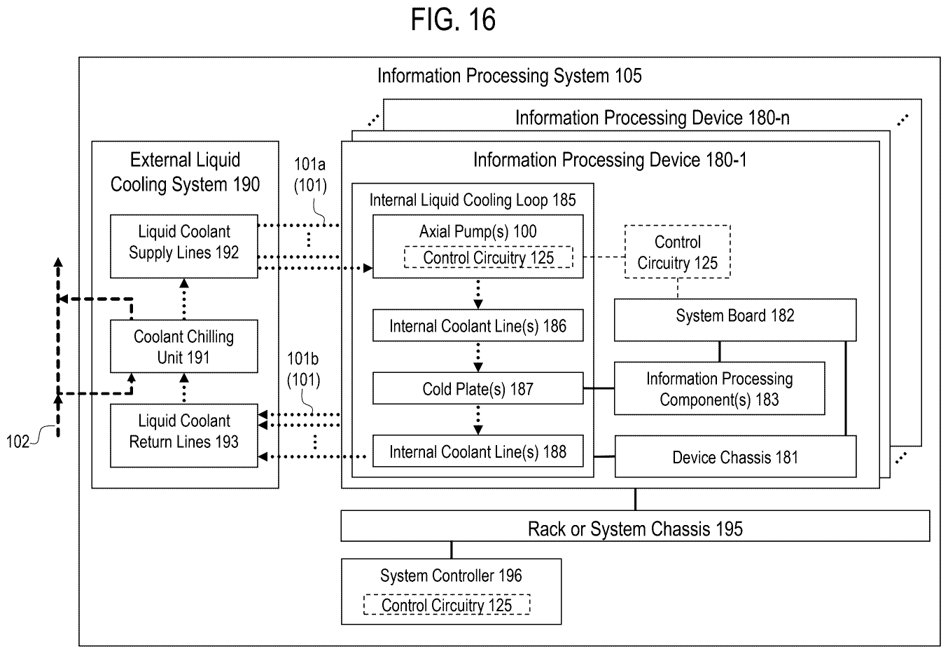

The axial pump 100 can be used in various applications, and in particular may be well suited for use in liquid cooling of information processing devices or systems. In some examples, the axial pump 100 can have a very small form factor, which allows it to be deployed within the limited space constraints often encountered in liquid cooling information processing devices or systems. Specifically, the small form factor of the axial pump 100 can make it well suited for deployment within the chassis of an information processing device, where space is highly limited. FIG. 15, described below, illustrates one example information processing device 180 in which axial pump 100 may be deployed. FIG. 16, described below, illustrates one example information processing system 105 in which pump 100 may be deployed. Note that “information processing device” refers to an electronic device comprising a system board with a processor configured to perform information processing functions, such as an individual server or networking device, whereas “information processing system” refers to a larger system in which one or more such information processing devices may be deployed. For example, a high-performance compute (HPC) system may comprise multiple individual server trays/blades that work together in a coordinated fashion, and in such a context each individual server tray/blade may be referred to as an information processing device while the HPC system as a whole may be referred to as an information processing system. As another example, multiple rack-mountable servers may be mounted to a rack, and in such a context each individual server may be referred to as an information processing device while the rack and the multiple servers mounted thereto may be referred to collectively as an information processing system.

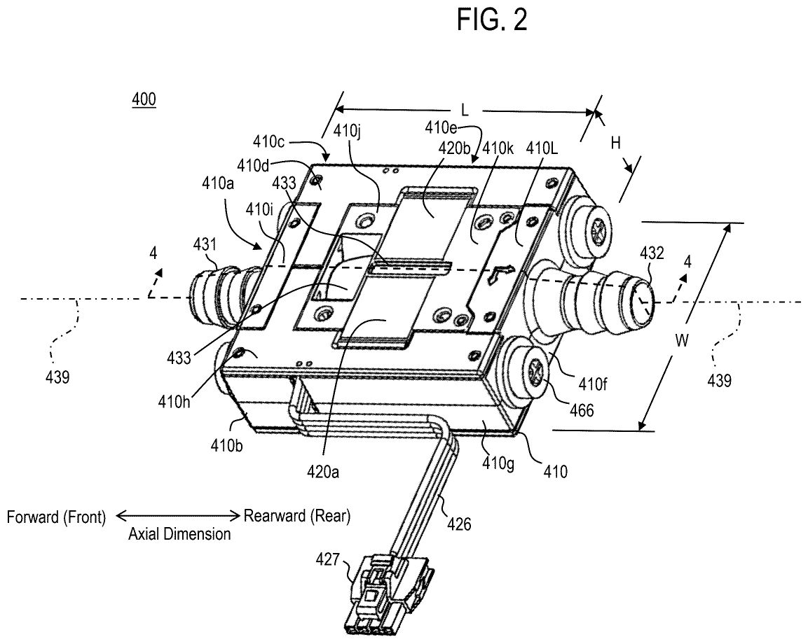

Turning now to FIGS. 2-14C, axial pump 400 (“pump 400”) will be described. The pump 400 is an example configuration of the pump 100 described above. Thus, some components of the pump 400 are similar to (e.g., example configurations of) corresponding components already described above, and thus the descriptions of the components of the pump 100 above are applicable to the similar components of the pump 400, and duplicative descriptions of certain aspects of the pump 400 may thus be omitted. Corresponding components may be referred to using reference numbers having the same last two digits, such as 110 and 410. It should be understood that the pump 400 is but one possible configuration of the pump 100, and the pump 100 is not limited to the pump 400. Similarly, the individual components of the pump 400 are examples of the corresponding individual components of the pump 100, but the individual components of the pump 100 are not limited to the corresponding components of the pump 400.

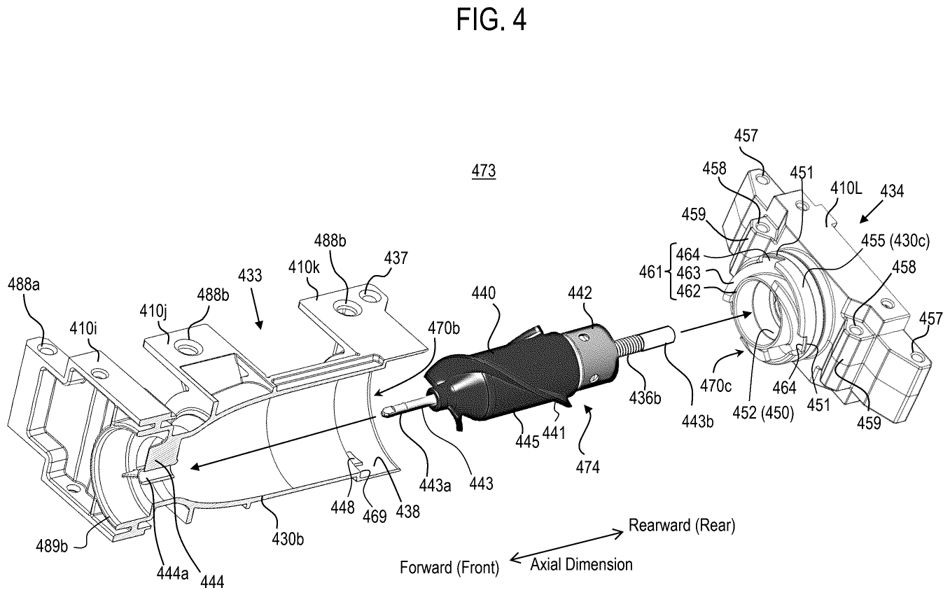

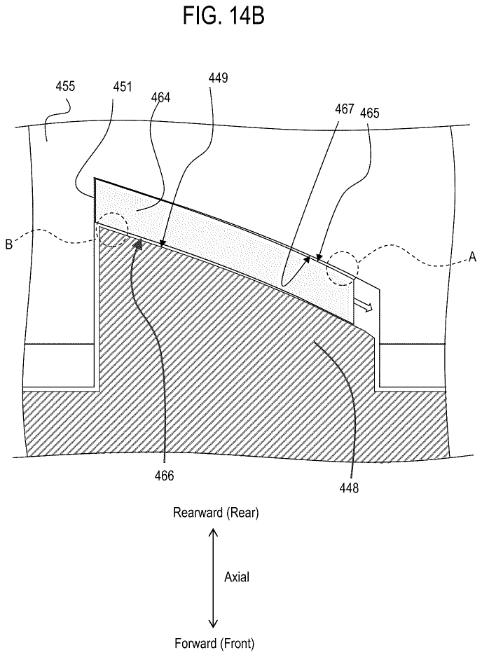

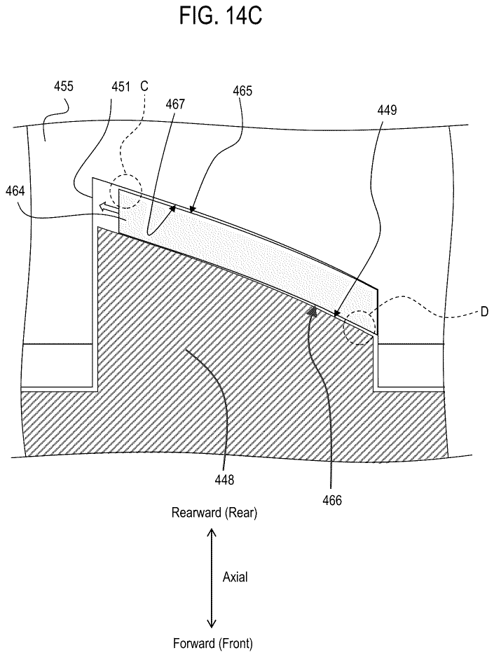

Various aspects of the pump 400 are visible in multiple figures, and different figures may show certain aspects better than others. Thus, rather than describing each of FIGS. 2-14C below in strict sequence, the various aspects of the pump 400 will be described in turn below with reference to some of the figures that are most relevant to the particular aspect under discussion. FIGS. 2, 3, and 5 show views of the full pump 400. FIGS. 4 and 6-13 show isolated portions of the pump 400 in various views. FIGS. 14A-C illustrate a clamping engagement of a keying tab 464 of the pump 400, as will be described below.

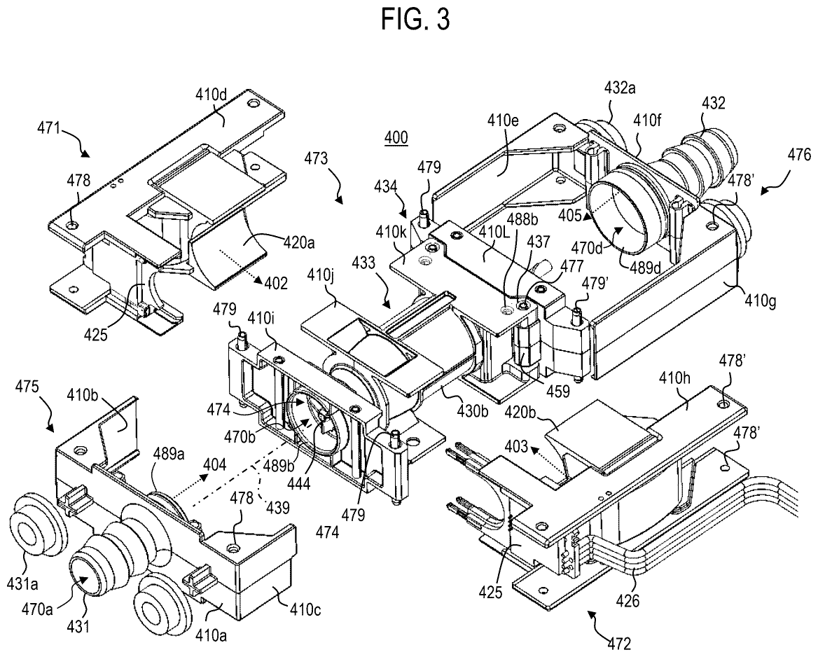

As shown in FIGS. 2 and 3, the pump 400 comprises multiple subassemblies, including a first stator subassembly 471, a second stator subassembly 472, an impeller chamber subassembly 473, an inlet subassembly 475, and an outlet subassembly 476. The inlet subassembly 475, impeller chamber subassembly 473, and outlet subassembly 476 together form a conduit 430, which includes a volume defining a liquid flow path for liquid coolant through the pump 400. More specifically, these subassemblies each include conduit walls which make up part of the conduit 430, with each conduit wall defining an internal volume (bore) which makes up a portion of the internal volume of the conduit 430 through which liquids. When the subassemblies are assembled, these conduit walls are connected such that their internal volumes fluidically communicate. Each of these subassemblies will be described in greater detail below.

As shown in FIGS. 2 and 3 the first and second stator subassemblies 471 and 472 comprise first and second stator portions 420a and 420b, respectively. In addition, the first and second stator subassemblies 471 and 472 comprise the PCBs 425, which make up a split PCA, such as the split PCA described in the U.S. patent application Ser. No. 17/976,406 entitled “AXIAL PUMP WITH SPLIT PRINTED CIRCUIT BOARD ASSEMBLY (PCA)” and filed on Oct. 28, 2022, the entire contents of which is incorporated herein by reference. The PCBs 425 are electrically coupled, for example via solder or other electrical connections to the first and second stator portions 420a and 420b, respectively. As shown in FIG. 3, the first and second stator subassemblies 471 and 472 are positioned on opposite lateral sides of the impeller chamber subassembly 473. Thus, during assembly of the pump 400 the first and second stator subassemblies 471 and 472 may be positioned as shown in the exploded view of FIG. 3 and then the stator subassemblies 471 and 472 may be moved laterally (along directions indicated by arrows 402 and 403) to bring the stator subassemblies 471 and 472 together around the impeller chamber subassembly 473. Once so assembled, the stator portions 420a and 420b are positioned adjacent to and radially surround the impeller chamber 433 (except for small regions at the top and bottom of the impeller chamber 433, which are not surrounded), as shown in FIG. 2. Moreover, as the first and second stator subassemblies 471 and 472 are coupled to the impeller chamber subassembly 473, the PCBs 425 become electrically coupled.

As shown in FIGS. 3 and 4, the impeller chamber subassembly 473 comprises an impeller chamber 433, an OGV chamber 434 which couples with the impeller chamber 433, and an impeller/rotor subassembly 474 housed within the impeller chamber 433 and OGV chamber 434. The impeller chamber subassembly 473 further comprises a first OGV segment 461 and a second OGV segment 450, which are part of an OGV 460 and will described in greater detail in another section below. The impeller chamber 433 comprises conduit walls 430b that form part of the conduit 430 and define a bore 470b. As shown in FIGS. 4, 5 and 7, a portion of the conduit walls 430b of the impeller chamber 433 forms an engagement portion 438 (an example of a “first engagement portion” referenced elsewhere herein), which defines a rear opening of the bore 470b, and another portion of the conduit walls 430b forms an engagement portion 489b, which defines a front opening of the bore 470b. The OGV chamber 434 comprises conduit walls 430c that are another part of the conduit 430 and define a bore 470c. As shown in FIGS. 4, 5 and 7, a portion of the conduit walls 430c of the OGV chamber 434 forms an engagement portion 455 (an example of a “second engagement portion” referenced elsewhere herein), which defines a front opening of the bore 470c, and another portion of the conduit walls 430c forms an engagement portion 489d, which defines a rear opening of the bore 470c. The engagement portions 438, 455, 489c, and 489d are configured to mate with one another and/or other engagement portions to fluidically couple various portions of the conduit 430 together. In particular, when the chambers 433 and 434 are coupled, their respective engagement portions 438 and 455 mate, resulting in their respective bores 470b and 470c being fluidically connected to each other. Mating of the engagement portions 489c and 489d will be described below in relation to inlet subassembly 475 and outlet subassembly 476

As suggested by the arrows in FIG. 4 when the impeller chamber subassembly 473 is assembled, the impeller/rotor subassembly 474 is positioned partially inside the bore 470b and partially inside the bore 470c. As shown in FIG. 4, the impeller/rotor subassembly 474 comprises an impeller 440 coupled to a rotor 442, which is in turn coupled to a shaft 443. The impeller 440 comprises an impeller body 445, blades 441 protruding radially from the impeller body 445 and spiraling circumferentially and axially around and along the outer surface of impeller body 445.

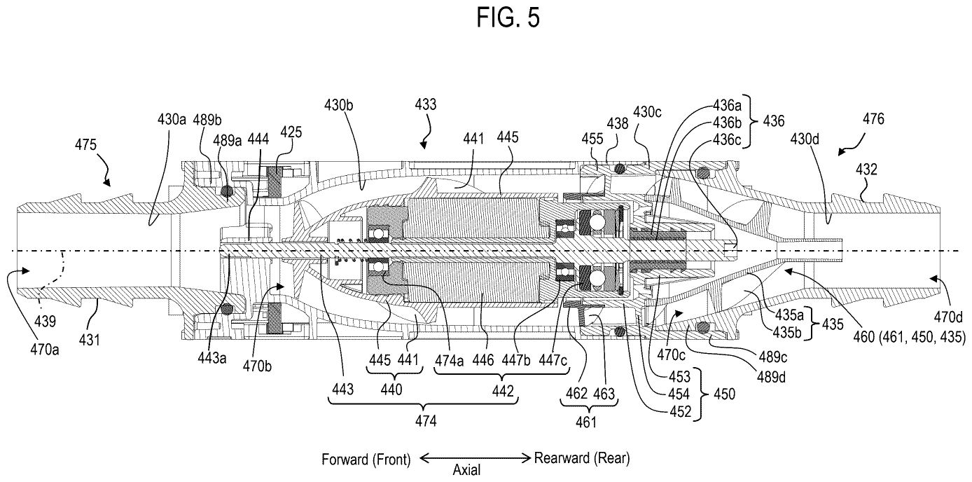

As shown in FIG. 5, the rotor 442 comprises magnets 446 which are distributed around the axis 439. The rotor 442 further comprises bearings 447 that rotatably coupled the rotor 442 to the shaft 443, so that rotor 442, and impeller 440 coupled thereto, can rotate about shaft 443. These bearings 447 may include front radial bearings 447a, rear radial bearings 447b, and rear thrust bearings 447c. The rotor 442 may be coupled to the impeller 440 by insertion of the rotor 442 into a hollow interior volume of the impeller body 445, wherein they may be fixedly joined together by press-fitting, adhesive, and/or other joining techniques.

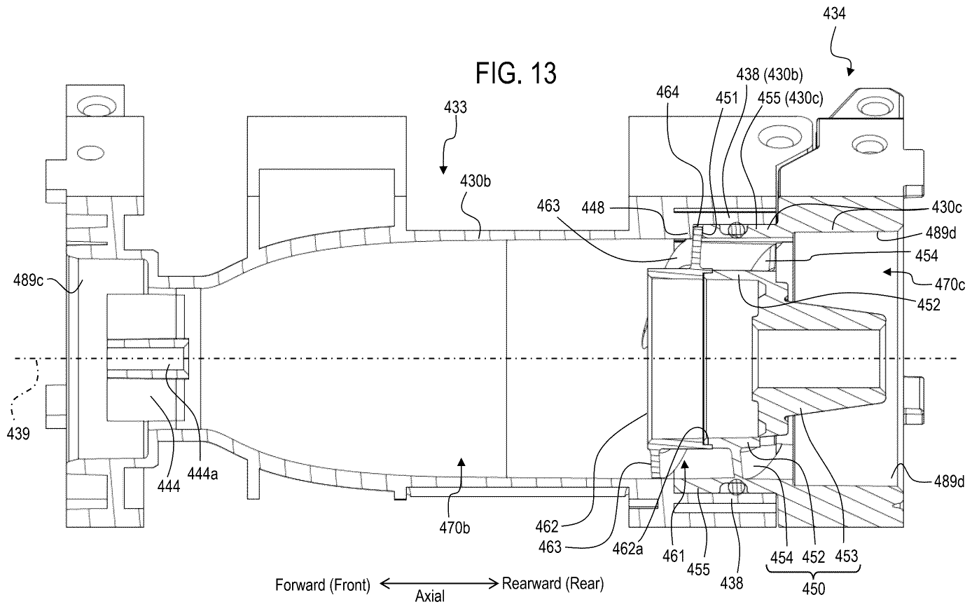

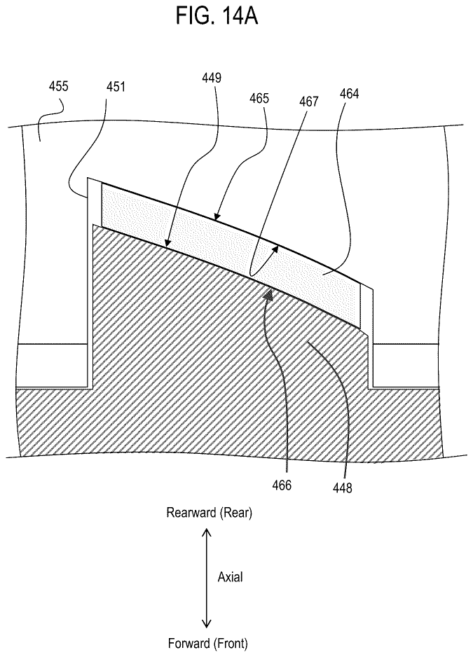

Once the impeller/rotor subassembly 474 is assembled, it may be inserted into the conduit 430 and the shaft 443 may be coupled to the conduit 430. For example, a rear end 443b of the shaft 443 may be inserted in and coupled to a rear support 453 of the OGV chamber 434, as shown in FIG. 5. As shown in FIGS. 5 and 13, the rear support 453 is part of the second OGV segment 450. Then, the OGV chamber 434 may be coupled to the impeller chamber 433 (by mating the engagement portions 455 and 438), and during this coupling a front end 443a of the shaft 443 is inserted into a hub 444a in a front support 444 of the impeller chamber 433, as shown in FIG. 5. After this, the impeller 440 and a portion of the rotor 442 are contained within the impeller chamber 433, another portion of the rotor 442 is contained in the OGV chamber 434, and the shaft 443 is contained in both chambers 433 and 434. The shaft 443 is fixedly attached to rear support 453, which is in turn fixed relative to conduit walls 430c of the OGV chamber 434, and therefore the shaft 443 is fixed relative to the conduit 430. Thus, as the rotor 442 and impeller 440 rotate about the shaft 443, they also rotate relative to the conduit 430.

In some examples, the coupling between the shaft 443 and the rear support 453 includes an adjustment mechanism 436. The adjustment mechanism 436 may comprise a nut 436a, a set screw 436b (formed by threads in an outer surface of the shaft 443), and a socket 436c (formed in the end of the shaft 443). The nut 436a is attached to the rear support 453 and receives the set screw 436b to fixedly couple the shaft 443 to the rear support 453. Moreover, rotation of the shaft 443 relative to nut 436a causes shaft 443 to translate axially relative to rear support 453. Socket 436c receives a tool to allow rotation of the shaft 443 in this manner. The adjustment mechanism 436 allows an axial position of the impeller/rotor subassembly 474 to be adjusted after assembly, which can allow for a smaller gap to be achieved between impeller blades and conduit 430 walls, which improves pump efficiency.

The impeller chamber 433 and OGV chamber 434 comprise various support structures that also form part of the housing 410 and which facilitate joining of the other subassemblies together. For example, as shown in FIG. 4, the OGV chamber 434 comprises fastener holders 459 with holes 458 to receive fasteners 477. As shown in FIGS. 3 and 4 the impeller chamber 433 comprises holes 437, and when the impeller chamber 433 and OGV chamber 434 are coupled together the holes 437 align with the holes 458. Thus, as shown in FIG. 3 a fastener 477 is inserted through the holes 437 and 458 to secure the impeller chamber 433 and OGV chamber 434 in the coupled state. In addition, as shown in FIG. 4, the OGV chamber 434 also comprises holes 457, which receive fasteners 479, as shown in FIG. 3. Similarly, the impeller chamber 433 comprises holes 488a, as shown in FIG. 4, to receive fasteners 479, as shown in FIG. 3. These fasteners 479 are used to couple the various subassemblies together, as will be described below. In some examples, the impeller chamber 433 may also comprise holes 488b, which may be used to fill the pump 400 with epoxy (or other filler material) after assembly to make the pump 400 water resistant and also to aid with transfer of heat from pump 400 components into the coolant by removing air gaps. Furthermore, the impeller chamber 433 and/or OGV chamber is/are coupled to housing portions 410i, 410j, 410k, and 410L.

The inlet subassembly 475 comprises the inlet 431, an engagement portion 489a, vibration isolators 431a, and portions 410a, 410b, and 410c of the housing 410. The inlet subassembly 475 also comprises conduit walls 430a that form part of the conduit 430 and define a bore 470a. The inlet 431 comprises a portion of the conduit walls 430a, including a portion forming a front opening into bore 470a, and the engagement portion 489a comprise another portion of the conduit walls 430a, including a portion forming a rear opening into bore 470a. The outlet subassembly 476 comprises the outlet 432, an engagement portion 489d, vibration isolators 432b, and portions 410e, 410f, and 410g of the housing 410. The outlet subassembly 476 also comprises conduit walls 430d that form part of the conduit 430 and define a bore 470d. The outlet 432 comprises a portion of the conduit walls 430d, including a portion forming a rear opening into bore 470d, and the engagement portion 489d comprise another portion of the conduit walls 430d, including a portion forming a front opening into bore 470d. The outlet 432 and the engagement portion 489d comprise conduit walls 430d that form part of the conduit 430 and define a bore 470d. As shown in FIG. 5, the outlet 432 may also comprise a third OGV segment 435 disposed in bore 470d, which is described in more detail below. In the illustrated example, the inlet 431 and outlet 432 comprise hose barb couplings. In other examples, other types of liquid couplings may be substituted for the hose barb couplings. The pump 400 may be coupled to another device (e.g., a chassis of a computing device in which the pump 400 is disposed) via the vibration isolators 431a and 432b. The vibration isolators 431a and 432b may be rubber, silicon, or another compliant material that helps to absorb vibrations generated by the pump 400 and prevent (or reduce) the transmission of these vibrations to the device in which the pump 400 is disposed. As shown in FIGS. 3 and 5, the inlet 431 is connected with the impeller chamber 433 by mating of the engagement portion 489a with the engagement portion 489b of the impeller chamber 433, which fluidically connects the bores 470a and 470b. The outlet 432 is connected with the OGV chamber 434 by mating of the engagement portion 489d with the engagement portion 489c of OGV chamber 434, which fluidically connects the bores 470c and 470d.

In addition, each of the inlet and outlet subassemblies 475 and 476 comprises portions of the housing 410. As shown in FIG. 3, the impeller chamber 433 and OGV chamber 434 may be coupled together to form impeller chamber subassembly 473 and the inlet and outlet subassemblies 475 and 476 may be positioned on opposite axial sides of the subassembly 473. Thus, during assembly of the pump 400 the inlet and outlet subassemblies 475 and 476 may be positioned as shown in FIG. 3 and then moved towards one another (along directions indicated by arrows 404 and 405) until the inlet 431 is fluidically coupled with impeller chamber 433 on one side of subassembly 473 and the outlet 432 is fluidically coupled with the OGV chamber 434 on the opposite side of the subassembly 473. In some examples, this assembly step may occur after the two stator subassemblies 471 and 472 have been assembled onto the impeller chamber subassembly 473. Once the inlet 431, outlet 432, impeller chamber 433, and OGV chamber 434 are coupled together, they together form the conduit 430 through which liquid coolant may flow along a central axis 439 thereof.

As mentioned above, the pump 400 comprises a housing 410. This housing 410 may be made up of multiple portions that are joined together. Specifically, the subassemblies described above may comprise these portions of the housing 410. In particular, the housing 410 comprises inlet end wall portion 410a and lateral wall portions 410b and 410c coupled to inlet end wall portion 410a. These portions 410a-c are part of the inlet subassembly 475. The housing 410 further comprises outlet end wall portion 410f and lateral wall portions 410g and 410e. These portions 410e-g are part of the outlet subassembly 476. When assembled, the aforementioned portions 410a-c and 410e-g define the perimeter side walls of the housing 410. The housing 410 also comprises top portion 410d which is coupled to the first stator portion 420a and part of the first stator subassembly 471, and top portion 410h which is coupled to the second stator portion 420b and part of the second stator subassembly 472. The housing also comprises top housing portions 410i, 410j, 410k, and 410L which are coupled to the conduit 430 and are part of the impeller chamber subassembly 473. The top portions 410d, 410h, and 410i-410L form the top face of the housing 410. Note that the top face of the housing 410 is not necessarily uniform and does not necessarily fully cover all of the pump 400. For example, a top of the stator portion 420a and 420b may be exposed and approximately coplanar with the top face of the housing 410 (this may allow the height dimension of the pump 400 to be reduced to the absolute minimum possible for a given size of stator 420). Some of the housing portions may include holes 478 (only some are labeled) that are arranged to receive a fastener 479 to couple the subassemblies together. For example, in some implementations including the one illustrated in FIG. 3, the impeller chamber subassembly 473 comprises fasteners 479 in the form or pins, such as spring-biased push pins, and each of these may be inserted into holes 478 of one more the subassemblies to secure the respective subassemblies together. A single fastener 479 may be inserted through two holes 478 of two different subassemblies—for example, the fastener labeled 479′ in FIG. 3 may be inserted into the two holes labeled 478′ which are part of the stator subassembly 472 and the outlet subassembly 476. The other fasteners 479 and holes 478 may be similarly joined.

The bottom portion of the housing 410 (which is generally not visible in the figures and is not labeled herein) may be similarly constructed as the top portion thereof, and thus duplicative description of these portions is omitted.

The OGV 460 and associated structures will now be described in greater detail. As mentioned above, in this example the OGV 460 is a segmented OGV and comprises a first OGV segment 461, a second OGV segment 450, and a third OGV segment 435. In an assembled state of the pump 400, these segments 461, 450, and 435 are arranged in series along axis 439 and coupled together, as shown in FIG. 5.

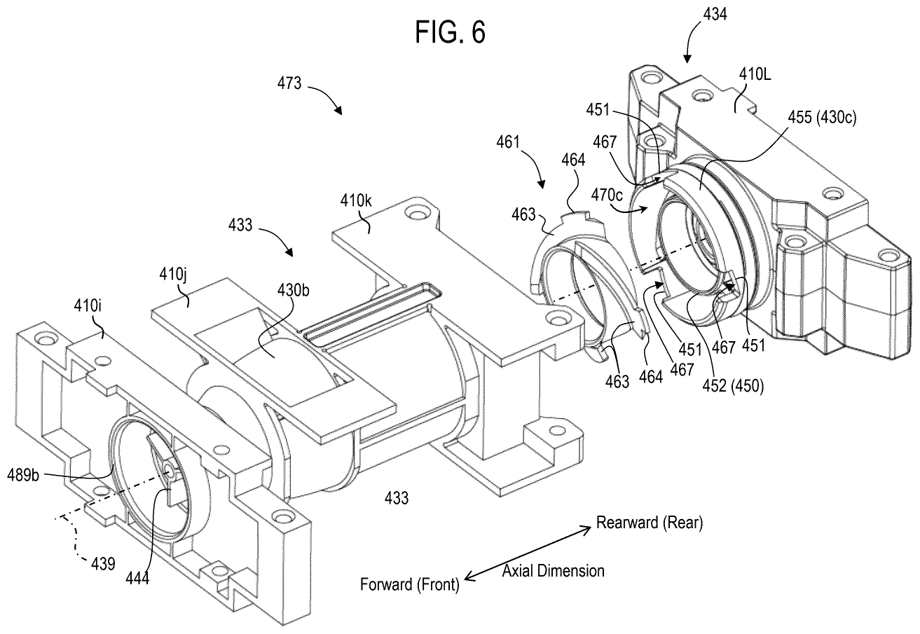

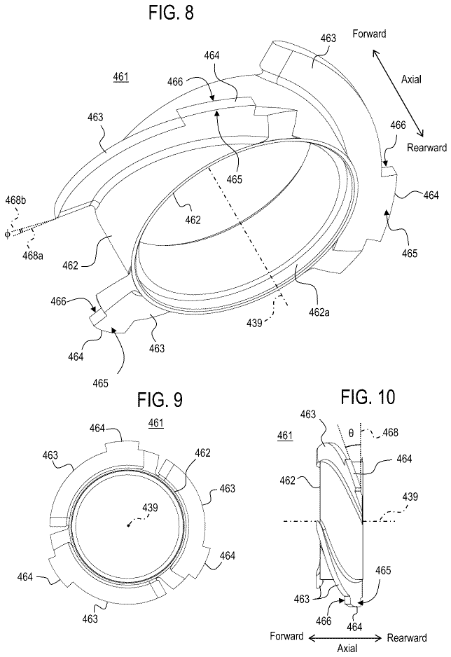

As shown in FIGS. 6, 7, and 13, the first OGV segment 461 is disposed at a mating point of the impeller chamber 433 and the OGV chamber 434, and is surrounded axially by both of the engagement portions 438 and 455. As shown in FIGS. 8-10, the first OGV segment 461 comprises a central ring 462 and three vanes 463 protruding radially from and spiraling axially and circumferentially around the central ring 462. Central ring 462 is one example of the “first central body” mentioned elsewhere herein, and vanes 463 are one example of the “first vanes” mentioned elsewhere herein. More or fewer vanes 463 could be provided in other examples. A central axis of the ring 462 is the same as (coaxial with) the rotation axis 439. The hollow interior of the central ring 462 may provide a space into which a rear end of rotor 442 can be received when pump 400 is assembled (see FIG. 5). During operation, liquid may flow in the space between the central ring 462 and the conduit walls 430b and 430c which surround the first OGV segment 461 (the hollow interior of the central ring 462 does not form part of the primary flow path for liquid, although some liquid can be found therein).

In addition, the first OGV segment 461 comprises keying tabs 464, which protrude radially from the top edges of the vanes 463. In this example, each vane 463 has one keying tab 464, with there being three of each. But fewer or more keying tabs 464 and/or vanes 463 could be provided in other examples, and each vane 463 does not necessarily have its own keying tab 464 in some examples. Each keying tab 464 comprises a first axial tab surface 465 that faces generally in an axially rearward direction. Each keying tab 464 also comprises a second axial tab surface 466, opposite the first axial tab surface 465, which faces generally in an axially forward direction.

Each keying tab 464 also follows the same sloped/spiraling path as the vane 463 from which is protrudes. Thus, there is a smooth continuous transition from the axial faces of the vanes 463 to the axial faces of the keying tabs 464. As shown in FIG. 10, in this example, the vanes 463 and keying tabs spiral circumferentially around and axially along the ring 462 at a wrapping angle θ relative to a plane 468 perpendicular to the rotation axis 439. In some examples, wrapping angle θ is about 15°. In other examples, a larger or smaller wrapping angle could be used. In addition, the wrapping angle may vary along the axial length of the OGV 460. The vanes 463 and keying tabs 464 are also tilted such that, as they protrude radially from the ring 462, their direction of protrusion 468a is tilted away from being perfectly radial (i.e., perpendicular to axis 439) by some tilt angle φ (in FIG. 10, the line 468b is a radial line perpendicular to axis 439). In some examples, the tilt angle φ is about 4°. References herein to the vanes and tabs protruding radially should be understood as meaning that they protrude generally in a radial direction, meaning a direction within 45° of perfectly radial.

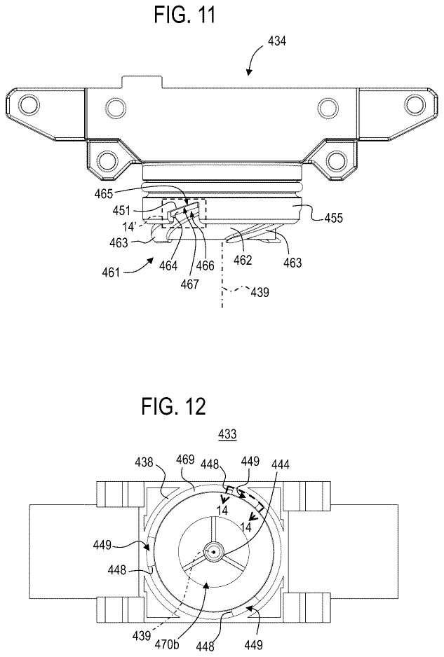

As shown in FIG. 11, the first OGV segment 461 is configured to be coupled to the engagement portion 455 of the OGV chamber 434. The OGV chamber 434 comprises keying slots 451 configured to receive the keying tabs 464 when the first OGV segment 461 is coupled to the OGV chamber 434, as shown in FIG. 11. As shown in FIG. 6, the keying slots 451 are arranged circumferentially around the engagement portion 455 at locations corresponding to those of the keying tabs 464. Each keying slot 451 is recessed axially rearward from a front (leading) edge of the engagement portion 455. Furthermore, each keying slot comprises a sloped axial slot surface 467, which faces axially forward. As shown in FIG. 11, when the first OGV segment 461 is coupled to the engagement portion 455, the first axial tab surface 465 contacts the axial slot surface 467. The axial slot surface 467 is complementary to the first axial tab surface 465 such that they make flush contact with one another, e.g., the axial slot surface 467 may be sloped to follow the same spiral path as the first axial tab surface 465, with wrap and tilt angles the same as or similar to θ and φ.

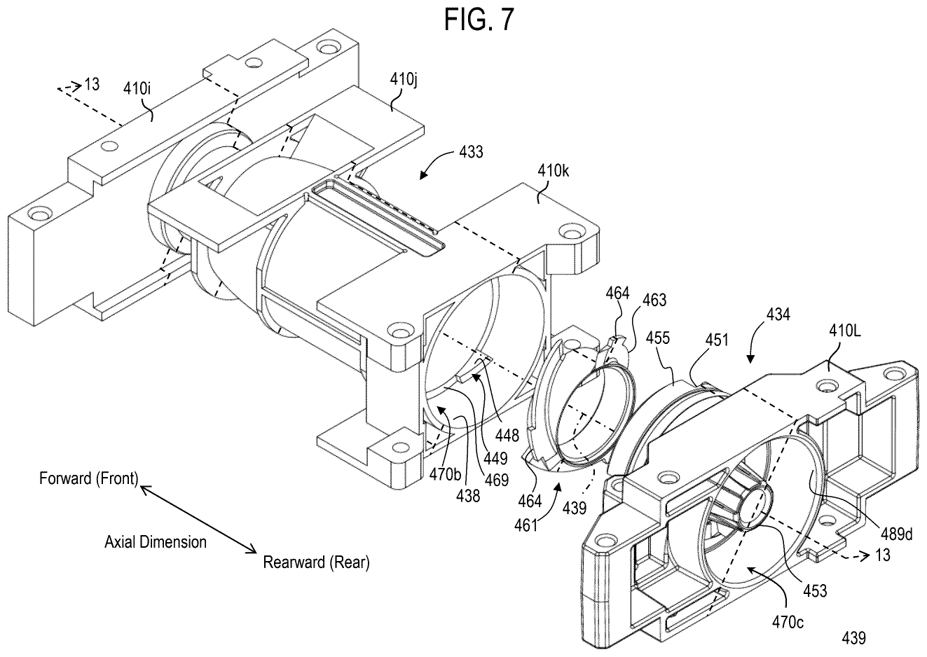

As shown in FIG. 7, the impeller chamber 433 has an engagement portion 438 that mates with the engagement portion 455 of the OGV chamber 434. As the engagement portions 438 and 455 mate, the first OGV segment 461, which is coupled to the engagement portion 455, is received with the engagement portion 438, as shown in FIG. 13. As shown in FIGS. 7 and 12, the impeller chamber 433 also comprises clamping supports 448 that protrude radially inwardly from the inner surface of the engagement portion 438 and axially rearward from a ledge 469 at a junction where the engagement portion joins a remainder of the impeller chamber 433. As shown in FIG. 12, the clamping supports 448 are arranged circumferentially around the engagement portion 438 at locations corresponding to those of the keying tabs 464. Each support 448 comprises a sloped axial support surface 449, which faces axially rearward. As shown in FIGS. 13 and 14A, when the engagement portion 438 mates with the engagement portion 455, the axial support surface 449 contacts the second axial tab surface 466. The axial support surface 449 is complementary to the second axial tab surface 466 such that they make flush contact with one another, e.g., the axial support surface 449 may be sloped to follow the same spiral path as the second axial tab surface 466, with wrap and tilt angles the same as or similar to θ and φ.

Thus, as shown in FIGS. 13 and 14A, when the engagement portion 438 mates with the engagement portion 455, the keying tab 464 is clamped between the support 448 on one side and the keying slot 451 on the other side, with flush contact between the first axial tab surface 465 and the axial slot surface 467 and between the second axial tab surface 466 and the axial support surface 449. This arrangement securely affixes the first OGV segment 461 relative to second OGV segment 450. In this context, “affixes” means that relative translation and relative rotation between first and second OGV segments 461 and 450 is prevented, including rotation about axis 439 (e.g., roll), rotation about axes perpendicular to axis 439 (e.g., pitch and yaw), and translation in any direction.

In some examples, the clamping of the keying tabs 464 also causes, assists in, and/or maintains a clocking of the first OGV segment 461 relative to second OGV segment 450 about the axis 439. This clocking may occur automatically, in some examples, a result of engagement of the keying tabs 464 with the keying slots 451 and/or the clamping supports 448. For instance, the clocking of the first OGV segment 461 relative to second OGV segment 450 may occur in part by constraints on circumferential movement of keying tabs 464 imposed by the side walls of the keying slots 451. In other words, simply by inserting the keying tabs 464 into the keying slots 451, the first OGV segment 461 is clocked, to a certain degree of precision, relative to the second OGV segment 450. This provides a gross level of clocking, which may be sufficiently precise to achieve desired performance in some examples.

However, in some examples, more precision may be desired, in which case additional clocking (beyond the gross clocking achieved by insertion of the keying tabs 464 into the keying slots 451) may be performed. In some examples, more precise clocking may be provided automatically by the clamping of the keying tabs 464 between the axial surfaces of the keying slots 451 and clamping supports 448. In other examples, more precise clocking may be provided manually, e.g., by a person or machine assembling the pump.

Automatic clocking from the clamping of the keying tabs 464 may occur, in some examples, due to the spiraling path that the keying tabs 464 follow and the complementary slopes of the engaging axial surfaces of the keying slots 451 and clamping supports 448. The shapes of these surfaces may result in there being only one orientation (assuming ideal surfaces) or a limited range or orientations (considering manufacturing tolerances) which will allow for flush contact to occur between all of the engaging axial surfaces. This range of orientations may be referred to herein as “clocked” orientations. If the first OGV segment 461 is outside the range of clocked orientations, then there will not be flush contact between the engaging axial surfaces. For example, FIG. 14B illustrates a hypothetical case where the keying tabs 464 are out of alignment to an extreme on one side of the keying slots 451, and, as can be seen, there is no flush contact between the first axial tab surface 465 and the axial slot surface 467 (notice region A) or between the second axial tab surface 466 and the axial support surface 449 (notice region B). As another example, FIG. 14C illustrates a hypothetical case where the keying tabs 464 are out of alignment to an extreme on the other side of the keying slots 451, and, as can be seen, there is no flush contact between the first axial tab surface 465 and the axial slot surface 467 (notice region C) or between the second axial tab surface 466 and the axial support surface 449 (notice region D). Consequently, in either state shown in FIGS. 14B and 14C, the clamping forces exerted on the keying tabs 464 will be unbalanced, resulting in the application of a tangential (circumferential) force being applied to the keying tabs 464. This creates a torque urging the first OGV segment 461 to rotate towards the clocked orientations, as indicated by the wide arrows in FIGS. 14B and 14C. When the first OGV segment 461 reaches the clocked orientation, as shown in FIG. 14A, then the engaging axial surfaces are all in flush contact and the tangential forces are balanced, thus holding the first OGV segment 461 in the clocked orientation.

In other examples, the additional precision in clocking may be achieved by explicit manual clocking by an assembler (human or machine). In some of these examples, the keying slots 451 may serve as alignment guides to assist in the manual clocking. For instance, a proper clocked orientation may be one which results in the keying tabs 464 being at a predetermined position relative to the keying slots 451, such as centered (circumferentially) in the keying slots 451 or pressed against one of the side walls of the keying slots 451, and the assembler can thus verify the proper clocking by observation of the relative position of the keying tabs 464 to the slots 451. In some examples, after manual clocking is performed, the clamping of the keying tabs 464 may hold the first OGV segment 416 in the clocked orientation by preventing subsequent rotation of the first OGV segment 416 relative to the second OGV segment 450. Without this holding, the first OGV segment 416 might rotate out of the clocked orientation, for example due to vibration, shock, forces exerted by the fluid flowing through the pump, etc.

As shown in FIG. 13, the second OGV segment is part of the OGV chamber 434 and is disposed within the bore 470c thereof. The second OGV segment 450 includes a central ring 452 and vanes 454 protruding radially from the central ring 452 and spiraling circumferentially about and axially along the ring 452. Central ring 452 is one example of the “second central body” mentioned elsewhere herein, and vanes 454 are one example of the “second vanes” mentioned elsewhere herein. The vanes 454 may connect the central ring 452 to conduit walls 430c of OGV chamber 434, which enclose and define the bore 470c. When the first OGV segment 461 is coupled to the engagement portion 455, an engagement portion 462a of the central ring 462 of the first OGV segment 461 engages with a front end of the central ring 452 of the second OGV segment 450. During operation, liquid may flow in the space between the central ring 452 and the conduit walls 430c which surround the second OGV segment 450 (the hollow interior of the central ring 452 does not form part of the primary flow path for liquid, although some liquid can be found therein).

As shown in FIG. 5, the third OGV segment 435 is part of the outlet 432 and is disposed in part in a bore 470d of the outlet 432, with a front part of the third OGV segment 435 protruding forward into the bore 470c of the OGV chamber 434 to mate with the rear of the second OGV segment 450. The third OGV segment 435 comprises a tapering central body 435a and vanes 435b that protrude radially from the body 435a and spiral circumferentially around and axially along the body 435a.

The first, second, and third OGV segments 461, 450, and 435 together from OGV 460. Liquid flows in the spaces between the conduit walls 430b, 430c, and 430d and the central rings/body 462, 462, and 435a of these segments 461, 450, and 435. The vanes 463, 454, and 435b extend into these spaces and guide the liquid to flow along spiraling flow paths defined thereby. The wrapping angles and geometries of the vanes 463, 454, and 435b may vary along the axial length of the OGV 460. As the liquid traverses the OGV 460, the swirling component of motion of the liquid flow may be reduced.

Turning now to FIG. 15, an information processing device 180 which utilizes the pump 100 will be described. The information processing device 180, which may be, for example, a server (e.g., a rack-mountable server, a server tray/blade of an HPC system or blade system, a desktop server, a hyperconverged infrastructure device, a data storage appliance, etc.), a networking device (e.g., network switch, network gateway, etc.), or other information processing device. As shown in FIG. 15, the information processing device 180 comprises a device chassis 181 (also “chassis 181), a system board 182 supported by the chassis 181, information processing components 183 electrically connected to the system board 182, and an internal liquid cooling loop 185 disposed in and supported by the device chassis 181.

The chassis 181 comprises walls, panels, and/or other support structures which support and/or house the other components. These may include a base, side walls, front panel, rear panel, and/or top cover/lid. The chassis 181 may also include cages or bays which receive components, such as drive cages, power supply unit cages, etc. The chassis 181 may also provide EMI shielding functions.

The system board 182 may comprise a motherboard, host-processor module (HPM), or similar printed circuit assemblies which comprise electrical circuitry and logic configured to control operations of the device 180. In particular, the system board 182 comprises at least a socket to which a processor (e.g., a central processing unit (CPU), system on chip (SoC), etc.) is mounted or mountable. System board 182 may also include any or all of: power regulation circuitry (e.g. voltage regulation modules (VRMs)), memory sockets to receive memory modules, connectors to mate with cables or pluggable modules, and control, management, and/or security circuitry (e.g., a baseboard management controller (BMC), a complex programmable logic device (CPLD), etc.).

The information processing components 183 may include the aforementioned processor which is mounted to a processor socket of the system board 182. The information processing components 183 may also include other components which participate in performing information processing functions of the device 180, such as a graphics processing unit (GPU), storage devices (e.g., solid state drives (SSDs)), memory modules (e.g., dual-inline memory modules (DIMMs)), network interface cards (NICs), storage array controllers or host-bus adapters (HBAs), pluggable optical transceivers, etc. Some of these information processing components 183 may be mounted and electrically connected directly to the system board 182 via sockets of the system board 182. Others of the information processing components 183 may be indirectly electrically connected to the system board 182 via cables.

Internal liquid cooling loop 185 comprises liquid cooling infrastructure arranged to cool one or more of the information processing components 183. The internal liquid cooling loop 185 is fluidically couplable to an external liquid cooling system (not illustrated) which supplies liquid coolant 101 thereto. More specifically, a flow of the liquid coolant 101 which is cool (denoted 101a in FIG. 15) is supplied from the external liquid cooling system to the internal liquid cooling loop 185, the liquid 101 is circulated through the internal liquid cooling loop 185 wherein the liquid 101 absorbs heat from one or more of the information processing components 183, and a flow of the now-heated liquid 101 (denoted 101b in FIG. 15) is then returned from the internal liquid cooling loop 185 to the external liquid cooling system, which cools the liquid 101 and recirculates it back to the internal liquid cooling loop 185.

The liquid cooling infrastructure of the internal liquid cooling loop 185 includes one or more instances of the axial pumps 100 arranged locally to the information processing device 180, meaning disposed within the device chassis 181 or disposed exterior to but immediately adjacent the chassis 181. The axial pump(s) 100 are configured to drive circulation of the liquid 101 through the internal liquid cooling loop 185. The axial pumps 100 can include any of the example implementation of the pumps 100 described herein, including but not limited to the pumps 400.

The liquid cooling infrastructure of the internal liquid cooling loop 185 further includes one or more cold plates 187, which are devices configured to thermally couple an information processing component 183 to the liquid 101, thereby allowing heat to flow from the component 183 into the liquid 101, cooling the component 183. For example, the cold plate 187 may comprise a thermally conductive body comprising a first surface configured to thermally coupe with the component 183 by direct contact or by mutual contact with an intermediary, such as a thermal interface material (TIM)), and a second surface configured to thermally couple with the liquid 101 by direct contact or by mutual contact with an intermediary, such that a conductive heat transfer path is formed from the component 183 to the liquid 101 via the cold plate 187. In some examples, the second surface of the cold plate 187 is an internal surface defining a conduit through which the liquid 101 passes with the liquid 101 directly contacting the second surface. In other examples, the liquid 101 may flow through a conductive tube (e.g., copper tube) which is in contact with the second surface of the cold plate 187.

The liquid cooling infrastructure of the internal liquid cooling loop 185 further includes internal coolant lines 186 which fluidically couple the other parts of the liquid cooling loop 185 together. These internal coolant lines 186 may include one or more individual coolant lines, such as tubes or pipes, and/or one or more manifolds which distribute one input into multiple outputs or combine multiple inputs into one output.

In FIG. 15, the flow path of the liquid 101 shown with dotted-line arrows suggests that the pump(s) 100 are upstream of the cold plates 187, with internal coolant line(s) 186 connected therebetween. But this is merely one example to schematically show a flow of liquid 101 through internal liquid cooling loop 185, and it should be understood that the components of the internal liquid cooling loop 185 could be arranged in any order or pattern desired, based on the needs of a particular device 180. For instances, the following is a non-exhaustive and non-limiting list of examples of configurations that the internal liquid cooling loop 185 could have: a single pump 100 is provided and it is disposed upstream of all the cold plate(s) 187; a single pump 100 is provided and it is disposed downstream of all the cold plate(s) 187; a single pump 100 is provided and it is disposed between two or more cold plate(s) 187; multiple pumps 100 are provided and all are upstream of all the cold plate(s) 187; multiple pumps 100 are provided and all are downstream of all the cold plate(s) 187; multiple pumps 100 are provided and some (or all) are in between two or more of the cold plates 187; multiple pumps 100 are provided and some are upstream of all the cold plate(s) 187 and others are downstream of all the cold plates 187. Furthermore, the locations, numbers, and types of internal coolant line(s) 186 are not limited and can be arranged as desired to fit within the needs of a given device 180. For instance, one or multiple pumps 100 could be coupled directly to the external cooling system in some examples, while in other examples internal coolant lines 186 could be disposed between the pump(s) 100 and the external cooling system. As another example, one or multiple pumps 100 could be coupled directly to cold plate(s) 187 in some examples, while in other examples internal coolant lines 186 could be disposed between the pump(s) 100 and the cold plates 187.

As noted, in some examples, multiple pumps 100 may be provided in internal liquid cooling loop 185. This can be done to ensure redundancy in case one pump 100 fails, and/or to achieve certain desired flow characteristics that might otherwise be difficult (or impossible) to achieve with just one pump 100. For instance, in some examples multiple pumps 100 may be arranged in series with one another to allow the pressure of the liquid 101 in the loop 185 to be increased. For example, if a single pump can generate a pressure differential of X at a given flow rate, then N pumps in series can generate a pressure differential of about N·X (neglecting various losses) at the same flow rate. In some examples, multiple pumps 100 may be arranged in parallel with one another to allow the flow rate of the liquid 101 in the loop 185 to be increased. For example, if a single pump can generate a flow rate of Y at a given pressure, then N pumps in parallel can generate a flow rate of about N·Y (neglecting various losses) at that same pressure. In other examples, multiple pumps 100 may be arranged in parallel and in series, such as by providing multiple groups of pumps 100, wherein the pumps 100 within a same group are arranged in series relative to one another and each group is arranged in parallel relative to the other groups. This may allow both pressure and flow rate to be increased. In some examples, some of the pumps 100 could be provided as part of an integrated pump unit.

In some examples, the control circuitry 125 which controls the pump 100 may be part of the pump 100. In other examples, the control circuitry 125 is internal to the information processing device 180 but external to the pump 100. For instance, the control circuitry 125 may be mounted to, or part of, the system board 182, such as a BMC or other controller, or the control circuitry 125 may be part of a separate module which may be removably installed in device chassis 181. In other examples control circuitry 125 is external to information processing device 180. In some examples in which information processing device 180 comprises multiple pumps 100, each pump 100 has its own corresponding instance of control circuitry 125 (whether internal or external to pump 100) that controls operations of that pump 100. Accordingly, each pump 100 may be individually controllable (via a respective control circuitry 125) to individually adjust flow rates of the liquid 101. In some examples in which information processing device 180 comprises multiple pumps 100, multiple pumps 100 may be controlled by a shared instance of control circuitry 125 (whether internal or external to device 180).

Turning now to FIG. 16, an information processing system 105 which utilizes the axial pumps 100 will be described. The information processing system 105 comprises multiple information processing devices, which may include multiple instances of information processing device 180 and which are labeled 180-1 to 180-n in FIG. 16. Each of these information processing devices 180 may include its own internal liquid cooling loop 185, which may include one or more axial pumps 100 as described above in relation to FIG. 15. These pumps 100 can include any of the example implementation of the pumps 100 described herein, including but not limited to the pumps 400. Other aspects of the information processing devices 180 have already been described in relation to FIG. 15, and thus duplicative description of these in relation to FIG. 16 is omitted.

The information processing system 105 may further comprise a rack or system chassis 195 configured to receive and support the information processing devices 180. In some examples, the rack or system chassis 195 may comprise a standard server rack, configured to receive multiple rack mountable servers or other equipment. In other examples, the rack or system chassis 195 may include a system chassis configured to house multiple pluggable trays or blade servers, such as an HPC system chassis or blade system chassis. The information processing system 105 may further include a system controller 196, which orchestrates and/or controls certain operations of the information processing devices 180 and/or the system 105 as a whole.

In some examples, the information processing system 105 may also include an external liquid cooling system 190. The external liquid cooling system 190 is “external” in the sense that it is external to the information processing devices 180, in contrast to their individual internal liquid cooling loops 185. In some examples, external liquid cooling system 190 is disposed in the rack or system chassis 195, while in other examples the external liquid cooling system 190 may be disposed external to the rack or system chassis 195, such as in a coolant distribution unit (CDU). The external liquid cooling system 190 is configured to supply flows 101a of cool liquid coolant 101 to the information processing devices 180 via various liquid coolant supply lines 192, which may include tube, pipes, manifolds and/or various other liquid cooling infrastructure fluidically coupled together and, ultimately, to the internal liquid cooling loops 185 of the devices 180. The external liquid cooling system 190 is also configured receive return flows 101b of warmed liquid coolant 101 from the information processing devices 180 via various liquid coolant return lines 193 which may include tube, pipes, manifolds and/or various other liquid cooling infrastructure fluidically coupled together and, ultimately, to the internal liquid cooling loops 185 of the devices 180. The external liquid cooling system 190 may also include a coolant chilling unit 191, which receives the flows 101b of warmed liquid coolant 101 and removes heat therefrom, thereby generating the flows 101a of cool liquid coolant 101. The coolant chilling unit 191 may include, in some examples, a liquid-to-liquid heat exchanger that receives facility coolant 102 from a facility coolant line and transfers heat from the liquid 101 into the facility coolant 102 (the facility coolant 102 may remain isolated from the liquid 101, with heat exchange occurring via conduction through the heat exchanger). The facility coolant 102 may circulate through a larger facility (e.g., datacenter) in which the system 105 is deployed, and may remove heat from similar liquid cooling systems of multiple other systems. The facility coolant 102 may ultimately dissipate this heat, returning the facility coolant 102 to a predetermined cool temperature, via a facility cooling system, such as a chiller tower or other systems familiar to those in the art. In other examples, the coolant chilling unit 191 may include, in some examples, a liquid-to-air heat exchanger that receives cool air from the facility (e.g., conditioned air) and transfers heat from liquid 101 into the cool air.

In some examples, external liquid cooling systems 190 may further include one or more pumps (not illustrated), such as pumps in a CDU, which assist in circulating liquid 101 through external liquid cooling systems 190. In such examples, the pumps of the external liquid cooling systems 190 may provide a baseline level of pumping power and the axial pumps 100 inside the individual information processing devices 180 may supplement this pumping power. In other examples, the pumps 100 inside the devices 180 may allow for external pumps to be omitted from external liquid cooling systems 190 entirely, with the pumps 100 collectively driving circulation of liquid 101 not only through their respective internal liquid cooling loops 185 but also through the external liquid cooling system 190. Whether external pumps are provided or not, the pumps 100 local to the devices 180 may allow for individualized control of the flows of liquid 101 through the various information processing devices 180. This can allow for more efficient operation, as devices 180 can receive exactly the flow rate of liquid 101 that they need given their current operating conditions.

The control circuitry 125 may be configure to provide this control over the pumps 100 that is individualized at the device 180 level, for example by sensing temperatures or other paramters and controlling the pumps 100 based on the sensed paramters. As explained above, in some examples, control circuitry 125 is internal to each pump 100. In some examples control circuitry 125 is external to the pumps 100 and internal to the information processing devices 180. In some examples control circuitry 125 is external to the information processing devices 180. For instance, in some examples, control circuitry 125 may be part of the system controller 196, or some other part of the information processing system 105.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. An axial pump for delivering liquid coolant to cool an electronic device, comprising:
a conduit defining a flow path from an inlet of the conduit to an outlet of the conduit, the conduit including an impeller chamber and an outlet guide vane (OGV) chamber;
an impeller and a rotor coupled together and disposed in the impeller chamber, the rotor and impeller being rotatable together relative to the conduit about an axis of rotation extending parallel to the flow path;
a stator configured to drive rotation of the rotor; and
an OGV comprising:
a first OGV segment comprising first vanes and keying tabs protruding radially from the first vanes; and
a second OGV segment that is part of the OGV chamber, comprises second vanes, and is coupled to the first OGV segment,
wherein the OGV chamber comprises keying slots in which the keying tabs are received, the impeller chamber comprises clamping supports extending axially into the keying slots, and the keying tabs are axially clamped between the clamping supports and the keying slots.

2. The axial pump of claim 1,
wherein the OGV is configured to reduce swirling of the liquid coolant downstream of the impeller.

3. The axial pump of claim 1,
the first OGV segment is affixed relative to the second OGV segment by the clamping of the keying tabs between the clamping supports and the keying slots.

4. The axial pump of claim 3,
wherein the first OGV segment is affixed relative the second OGV segment without epoxy or adhesive.

5. The axial pump of claim 1,
the clamping of the keying tabs between the clamping supports and the keying slots constrains the first OGV segment to a predetermined orientation, about the axis of rotation.

6. The axial pump of claim 1,
the first OGV segment is clocked relative to the second OGV segment, about the axis of rotation, by the clamping of the keying tabs between the clamping supports and the keying slots.

7. The axial pump of claim 1,
wherein keying tabs each comprise a first axial tab surface and a second axial tab surface,
wherein the keying slots each comprise an axial slot surface in contact with the first axial tab surface of a corresponding one of the keying tabs,
wherein the clamping supports each comprise an axial support surface in contact with the second axial tab surface of a corresponding one of the keying tabs.

8. The axial pump of claim 7,
wherein the axial slot surfaces are in flush contact with the first axial tab surfaces, respectively; and
wherein the axial support surfaces are in flush contact with the second axial tab surfaces, respectively.

9. The axial pump of claim 7,
wherein the first OGV segment comprises a first central ring and the first vanes protrude radially from and spiral circumferentially around and axially along the first central ring,
wherein the keying tabs follow a same spiral path as the respective first vanes to which the keying tabs are coupled, and
wherein the axial slot surfaces and the axial support surfaces are sloped to be complementary to the keying tabs.

10. The axial pump of claim 1,
wherein the impeller chamber comprises a first engagement portion and the OGV chamber comprises a second engagement portion mated with the first engagement portion,
wherein the clamping supports are formed in the first engagement portion, and
wherein the keying slots are formed in the second engagement portion.

11. The axial pump of claim 10,
wherein the keying slots are recessed axially from a leading edge of the second engagement portion.

12. The axial pump of claim 10,
wherein the clamping supports protrude radially inward from an inner surface of the second engagement portion.

13. The axial pump of claim 12,
wherein the clamping supports protrude axially from a ledge at a junction of the second engagement portion with a remainder of the impeller chamber.

14. The axial pump of claim 1,
wherein the OGV chamber comprises conduit walls defining a bore forming a portion of the flow path, the second OGV segment disposed in the bore,
wherein the second OGV segment comprises a second central ring and the second vanes protrude radially from and spiral circumferentially around and axially along the second central ring, and
wherein the second vanes couple the second central ring to the conduit walls of the OGV chamber.

15. The axial pump of claim 14, further comprising:
a shaft to which the rotor is rotatably coupled,
wherein the second OGV segment comprises a rear support coupled to the second central ring, the rear support coupled to a rear end portion of the shaft.

16. The axial pump of claim 1,
wherein the OGV further comprises a third OGV segment that is part of the outlet and comprises a tapered central body and third vanes protruding from the tapered central body,
wherein the second OGV segment is axially adjacent and coupled to the third OGV segment.

17. An information processing device, comprising:
a system board;
an information processing component coupled to the system board;
a chassis housing the system board;
a cold plate thermally coupled to the information processing component; and
the axial pump of claim 1 disposed within the chassis, wherein the conduit of the axial pump is fluidically coupled with the cold plate.

18. A system, comprising:
a plurality of information processing devices, each comprising: a chassis; a system board disposed in the chassis; an information processing component coupled to the system board; a cold plate thermally coupled to the information processing component; and at least one axial pump according to claim 1 disposed in the chassis with the outlet of the conduit of the axial pump fluidically coupled with the cold plate; and
an external liquid cooling system comprising liquid coolant supply lines configured to supply liquid coolant to the axial pumps of the information processing devices, liquid coolant return lines configured to return liquid coolant from the axial pumps, and a coolant chilling unit configured to cool the liquid coolant.

19. The system of claim 18,
wherein the axial pumps are individually controllable to individually adjust flow rates of the liquid coolant through the information processing devices.

20. A method of manufacturing an axial pump, comprising:
inserting keying tabs of a first outlet guide vane (OGV) segment into corresponding keying slots in an OGV chamber comprising a second OGV segment;
coupling an impeller chamber, which houses an impeller/rotor subassembly, to the OGV chamber and, during the coupling, inserting clamping supports of the impeller chamber into the keying slots; and
affixing the first OGV segment relative to the second OGV segment by axially clamping the keying tabs between the clamping supports and the keying slots.
